(19) United States
(12) Patent Application Publication
(10) Pub. No.: US 2008/0105963 A1
(43) Pub. Date: May 8, 2008

(54) Stackable electronic device assembly

(75) Inventors: William Walter Carlson, San Jose, CA (US); Michael Warner, San Jose, CA (US); Salvador A. Tostado, Los Gatos, CA (US); John B. Riley III, Dallas, TX (US); Ronald Green, San Jose, CA (US); Ilyas Mohammed, Santa Clara, CA (US); Michael J. Nystrom, San Jose, CA (US); Rolfe Tyson Gustus, Fremont, CA (US); David R. Baker, Santa Clara, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/881,743

(22) Filed: Jul. 27, 2007

Related U.S. Application Data
(60) Provisional application No. 60/834,203, filed on Jul. 28, 2006.

(51) Int. Cl. H01L 23/02

(52) U.S. Cl. 257/686; 257/E23.172

(57) ABSTRACT

A stackable chip assembly is disclosed, as are many different embodiments relating to same. The chip assembly preferably includes at least two substrates with components mounted on each. The substrates are preferably situated with respect to one another such that components on one substrate extend towards the other substrate and vice versa. The components of each substrate preferably extend between each other. In addition various connections between the substrates are disclosed, as well as methods of constructing such chip assemblies.

### CROSS-REFERENCE TO RELATED APPLICATIONS

This application claims the benefit of the filing date of U.S. Provisional Patent Application No. 60/834,203 filed Jul. 28, 2006, the disclosure of which is hereby incorporated herein by reference.

This application is also related to commonly owned U.S. Provisional Patent Application No. 60/703,175 filed on Jul. 28, 2005 and entitled “STACKABLE ELECTRONIC DEVICE ASSEMBLY AND HIGH G-FORCE TEST FIXTURE,” commonly owned U.S. Utility patent application Ser. No. 11/495,287 filed on Jul. 28, 2006, naming Michael Warner, Ilyas Mohammed, Ronald Green and John Riley, III and entitled “STACKABLE ELECTRONIC DEVICE ASSEMBLY AND HIGH G-FORCE TEST FIXTURE,” and commonly owned U.S. Provisional Patent Application No. 60/834,202 filed on Jul. 28, 2006, naming Daniel Buckminster, Salvador Tostado and Apolinar Alvarez, Jr. and entitled “STACKABLE ELECTRONIC DEVICE ASSEMBLY AND METHOD,” the disclosures of which are hereby incorporated herein by reference.

### BACKGROUND OF THE INVENTION

Microelectronic elements such as semiconductor chips are typically provided in packages which provide physical and chemical protection for the semiconductor chip or other microelectronic element. Such a package typically includes a package substrate like a small circuit panel formed from a dielectric material and having electrically conductive terminals thereon. The chip is mounted on the panel and electrically connected to the terminals of the package substrate. Typically, the chip and portions of the substrate are covered by an encapsulant or overmolding, so that only the terminal-bearing outer surface of the substrate remains exposed. Such a package can be readily shipped, stored and handled. The package can be mounted to a larger circuit panel such as a circuit board using standard mounting techniques, most typically surface-mounting techniques. Considerable effort has been devoted in the art to making such packages smaller, so that the packaged chip occupies a smaller area on the circuit board. For example, packages referred to as chip-scale packages occupy an area of the circuit board equal to the area of the chip itself, or only slightly larger than the area of the chip itself. However, even with chip-scale packages, the aggregate area occupied by several packaged chips is greater than or equal to the aggregate area of the individual chips.

It has been proposed to provide “stacked” packages, in which a plurality of individual chip packages or units are mounted one above the other in a common package assembly. This common package assembly can be mounted on an area of the circuit panel which may be equal to or just slightly larger than the area typically required to mount a single package or unit containing a single chip. The stacked package approach thusly conserves space on the circuit panel. Chips or other elements which are functionally related to one another can be provided in a common stacked package assembly. The assembly may incorporate interconnections between these elements. Thus, the main circuit panel to which the assembly is mounted need not include the conductors and other elements required for these interconnections. This, in turn, allows use of a simpler circuit panel and, in some cases, allows the use of a circuit panel having fewer layers of metallic connections, thereby materially reducing the cost of the circuit panel. Moreover, the interconnections within a stacked package assembly often can be made with lower electrical impedance and shorter signal propagation delay times than comparable interconnections between individual units mounted on a circuit panel. This, in turn, can increase the speed of operation of the microelectronic elements within the stacked package as, for example, by allowing the use of higher clock speeds in signal transmissions between these elements.

One form of stacked package assembly which has been proposed heretofore is sometimes referred to as a “ball stack.” A ball stack assembly includes two or more individual units. Each unit incorporates a unit substrate similar to the package substrate of an individual unit, and one or more microelectronic elements mounted to the unit substrate and connected to the terminals on the unit substrate. The individual units are stacked one above the other, with the terminals on each individual unit substrate being connected to terminals on another unit substrate by electrically conductive elements such as solder balls or pins. The terminals of the bottom unit substrate may constitute the terminals of the entire assembly or, alternatively, an additional substrate may be mounted at the bottom of the assembly which may have terminals connected to the terminals of the various unit substrates. Ball stack packages are depicted, for example, in certain preferred embodiments of U.S. Published Patent Applications 2003/0107118 and 2004/0031972, the disclosures of which are hereby incorporated herein by reference.

In another type of stack package assembly sometimes referred to as a fold stack package, two or more chips or other microelectronic elements are mounted to a single substrate. This single substrate typically has electrical conductors extending along the substrate to connect the microelectronic elements mounted on the substrate with one another. The same substrate also has electrically conductive terminals which are connected to one or both of the microelectronic elements mounted on the substrate. The substrate is folded over on itself so that a microelectronic element on one portion lies over a microelectronic element on another portion, and so that the terminals of the package substrate are exposed at the bottom of the folded package for mounting the assembly to a circuit panel. In certain variants of the fold package, one or more of the microelectronic elements is attached to the substrate after the substrate has been folded to its final configuration. Examples of fold stacks are shown in certain preferred embodiments of U.S. Pat. No. 6,121,676; U.S. patent application Ser. No. 10/077,388; U.S. patent application Ser. No. 10/655,952; U.S. Provisional Patent Application No. 60/403,939; U.S. Provisional Patent Application No. 60/408,664; and U.S. Provisional Patent Application No. 60/408,644, the disclosures of which are hereby incorporated herein by reference. Fold stacks have been used for a variety of purposes, but have found particular application in packaging chips which must communicate with one another as, for example, in forming assemblies incorporating a baseband signal processing chip and radiofrequency power amplifier (“RFPA”) chip in a cellular telephone, so as to form a compact, self-contained assembly.

Despite all of the innovations discussed above, there remains room for improvement. For example, miniaturization of chip package assemblies is desired for use in munitions and munitions testing, among other applications. Chip assemblies for use in such applications must not only be relatively small, but also capable of withstanding relatively high G-forces. In addition to the packages themselves, a method of manufacturing miniaturized chip package assemblies is desired.

Therefore, there exists a need for a miniaturized stacked package assembly capable of withstanding harsh environments, such as high G-force applications. In addition, there is also a need for a method of manufacturing same.

### SUMMARY OF THE INVENTION

A first aspect of the present invention is a chip assembly. In accordance with certain embodiments such chip assembly include a first unit including a first substrate and one or more first electronic components mounted to the first substrate, a second unit including a second substrate and one or more second electronic components mounted to the second substrate, and a connection between the first and second substrates. The first and second units are preferably connected together so that the first electronic components project from the first substrate toward the second substrate and the second electronic components project from the second substrate toward the first substrate, and at least some of the first electronic components extend between at least some of the second electronic components.

Certain embodiments in accordance with the present invention may include different connections between the first and second substrates including, but not limited to, one or more solder balls, one or more pins, one or more spring loaded contacts, one or more screw/rivet connections, one or more wire loops, one or more plated vias, and one or more shoulder pins. In certain preferred embodiments, the total height between the first and second substrates is less than the total height of the first and second electronic components. In addition, an encapsulant and/or spacer block (with or without an encapsulant passage formed therethrough) may be disposed between the first and second units. Other spacer blocks may be employed which employ an electrical connection such as a via or trace.

Another aspect of the present invention is another chip assembly. Such second aspect assembly may include a first unit including a first substrate and one or more first electronic components mounted to the first substrate, a second unit including a second substrate and one or more second electronic components mounted to the second substrate, a third unit including a third substrate and one or more third electronic components mounted to the third substrate, and a connection between the first, second and third substrates. Preferably, the first, second and third units are connected together so that the first electronic components project from the first substrate toward the second substrate and at least some of the second electronic components project from the second substrate toward the first substrate, and so that the third electronic components project from the third substrate toward the second substrate and at least some of the second electronic components project from the second substrate toward the third substrate, and at least some of the first electronic components extending between at least some of said second electronic components and at least some of the third electronic components extending between at least some of the second electronic components. Similar variation connections discussed in conjunction with the first aspect may be utilized in conjunction with this second aspect, as can other variations to the overall assembly configuration/design.

### BRIEF DESCRIPTION OF THE DRAWINGS

A more complete appreciation of the subject matter of the present invention and the various advantages thereof can be realized by reference to the following detailed description in which reference is made to the accompanying drawings in which:

FIG. 1 is a side perspective view of a chip assembly in accordance with one embodiment of the present invention, with encapsulant removed therefrom.

FIG. 2 is an illustration of the interconnection process of two units with one another.

FIGS. 3A-3B are illustrations depicting one assembly manufacturing process in accordance with the present invention.

FIG. 4 is an illustration of the interconnections of a plurality of assemblies with one another.

FIG. 5 is a side perspective view of a chip assembly in accordance with another embodiment of the present invention, with encapsulant removed therefrom.

FIG. 6 is a cross sectional view of an unassembled chip assembly employing spring loaded electrical contacts in accordance with another embodiment of the present invention.

FIG. 7 is a cross sectional view of the chip assembly of FIG. 6 in an assembled state.

FIG. 8 is a cross sectional view of an unassembled chip assembly employing screws and rivets in accordance with another embodiment of the present invention.

FIG. 9 is a cross sectional view of an assembled chip assembly employing loops of wire in accordance with another embodiment of the present invention.

FIGS. 10a-10g illustrate different configuration loops of wire useable in the chip assembly of FIG. 9.

FIGS. 11a-11c are cross sectional views of a chip assembly employing vias, in different states of assembly.

FIG. 12 is a cross sectional view of an unassembled chip assembly employing should pins and three substrates in accordance with another embodiment of the present invention.

FIG. 13 is a cross sectional view of the unassembled chip assembly of FIG. 6 with a spacer block being utilized during assembly.

FIG. 14 is a perspective view of a plurality of the spacer blocks shown in FIG. 13.

FIG. 15 is a perspective view of a plurality of spacer blocks in accordance with another embodiment of the present invention, having vias formed therethrough.

FIG. 16 is an illustration of a single spacer block of FIG. 15.

FIG. 17 is a perspective view of a plurality of spacer blocks in accordance with another embodiment of the present invention, having vias formed therethrough.

FIG. 18 is a cross sectional view of a chip assembly employing one of the spacer blocks of FIG. 17.

FIG. 19 is a cross sectional view of a chip assembly employing spacer blocks having connections formed therethrough in accordance with the present invention.

FIG. 20 is an exploded view of two chip assemblies employing spacer blocks prior to one embodiment assembly process.

FIG. 21 is another exploded view of two chip assemblies employing spacer blocks prior to one embodiment assembly process.

FIG. 22 is yet another exploded view of two chip assemblies employing spacer blocks prior to one embodiment assembly process.

FIG. 23 is a perspective view of a plurality of spacer blocks in accordance with yet another embodiment of the present invention, having vias formed therethrough.

FIG. 24 is a cross section view of a chip assembly employing one of the spacer blocks of FIG. 23.

FIG. 25 is a perspective view of a plurality of spacer blocks in accordance with yet another embodiment of the present invention, having traces.

FIG. 26 is a cross section view of a chip assembly employing one of the spacer blocks of FIG. 25.

FIG. 27 depicts yet another embodiment chip assembly in accordance with the present invention.

FIG. 28 depicts a partially assembled shell with multiple assemblies of FIG. 27 therein.

FIG. 29 depicts a full assembled shell of FIG. 28.

FIG. 30 is a side cross sectional view of the shell of FIG. 29.

FIG. 31 is a top cross sectional view of the shell of FIG. 29.

### DETAILED DESCRIPTION

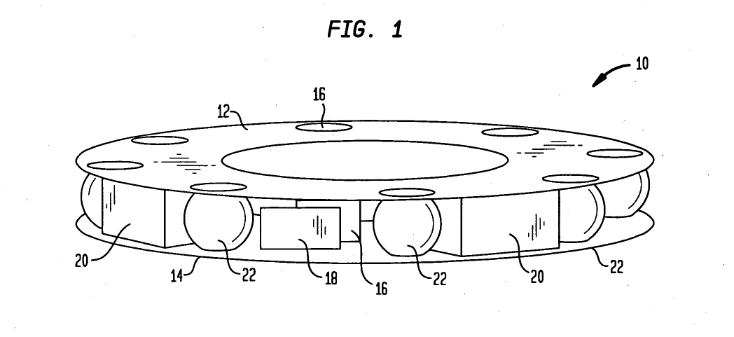

In accordance with the present invention, a miniaturized stacked package assembly is illustrated in FIG. 1, and is referred to throughout by reference numeral 10. As shown, assembly 10 includes two substrates 12 and 14, each with a plurality of electronic components, such as chips, mounted thereto. The substrate and component combination may be referred to as a unit. The components mounted to substrate 12 will be collectively referred to with reference numeral 16, and the components mounted to substrate 14 will be collectively referred to with reference numeral 18. Assembly 10 may further include spacers 20 for ensuring proper spacing between substrates 12 and 14 and solder balls 22 for connecting the substrates together. It is to be understood, that any type, size, shape or configuration substrates, components, spacers and/or solder balls may be utilized as one of ordinary skill in the art would readily recognize. For example, although depicted in the figures as having a circular shape, substrates 12 and 14 may be any shape. In addition, solder balls 22 may be solid core solder balls, or balls constructed completely of solder. Similarly, such connection elements may be pins, rods, or other structural and/or conductive elements, as will be discussed more fully below.

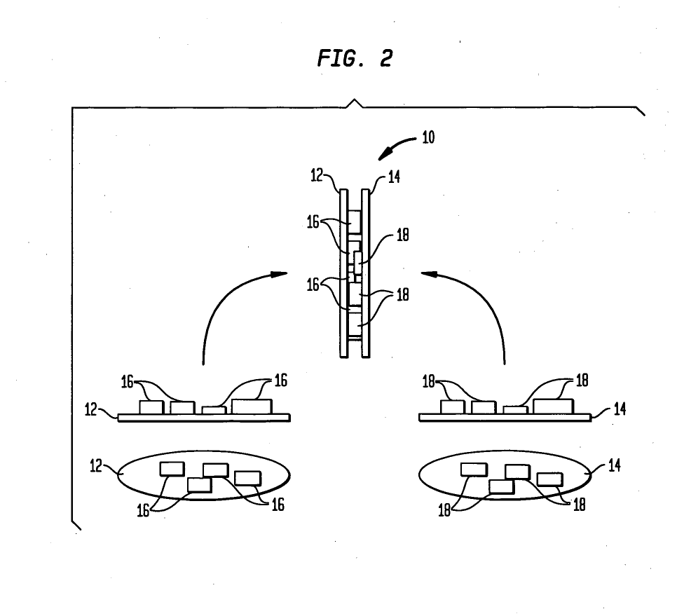

As best shown in FIG. 2, the various components 16 of substrate 12 are arranged so as to interconnect with the various components 18 of substrate 14, when the two substrates are sandwiched together. In the fully constructed assembly 10, the substrates are disposed so that the various electronic components face opposing substrates. Essentially, the components on each of the substrates are arranged so as to allow for a puzzle-like fit between the two complete substrates 12 and 14. In the preferred embodiment shown, it is noted that the components are collectively configured and sized, and the substrates are situated with respect to one another in a completed assembly 10, so that none of the components disposed on one substrate contacts the other substrate or any of the components thereon. However, it is clearly envisioned that other designs may include some contact between the components and opposite substrates. As shown, components 16 and 18 extend between each other in this puzzle-type fit. This allows for the distance between substrates 12 and 14 to be less than the total height of a combination of components 16 and 18.

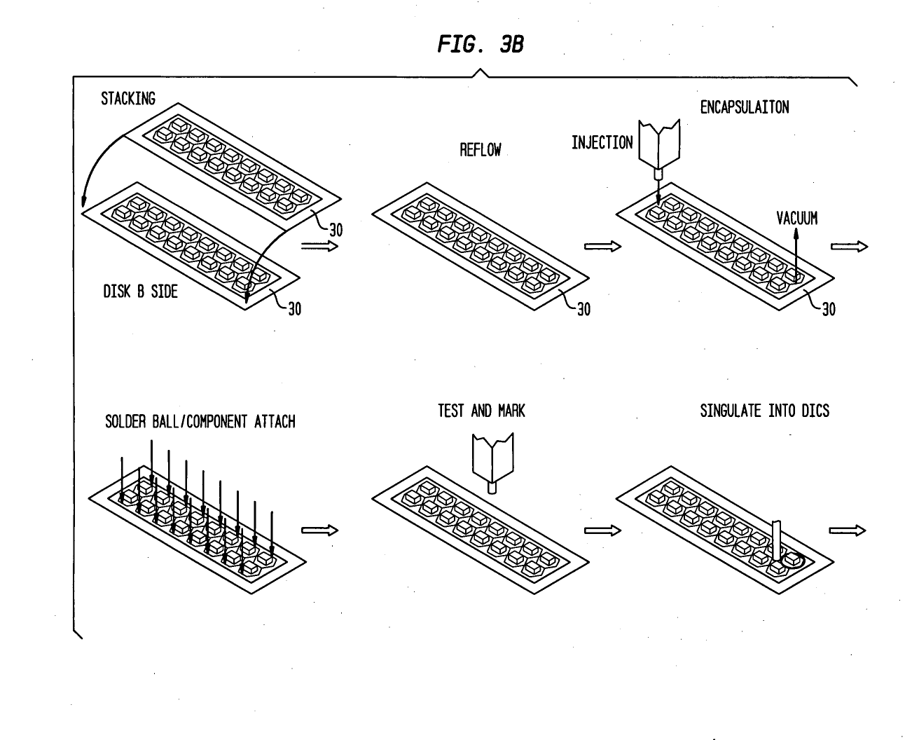

The configuration of the various components located on substrates 12 and 14, which allows the aforementioned puzzle-like fit or interconnection of the various components, also allows substrates 12 and 14 to be “stacked” or arranged with their top surfaces facing one another. This necessarily lowers the overall profile of assembly 10, which is beneficial in manufacturing and providing a reduced size assembly. In addition, this type of assembly configuration makes for a very stable and rugged package assembly 10. As best shown in FIG. 4, a completed assembly 10 is further assembled by injecting an encapsulant between substrates 12 and 14. This further stabilizes and strengthens the overall assembly 10, as well as possibly making the assembly impervious to certain environmental elements.

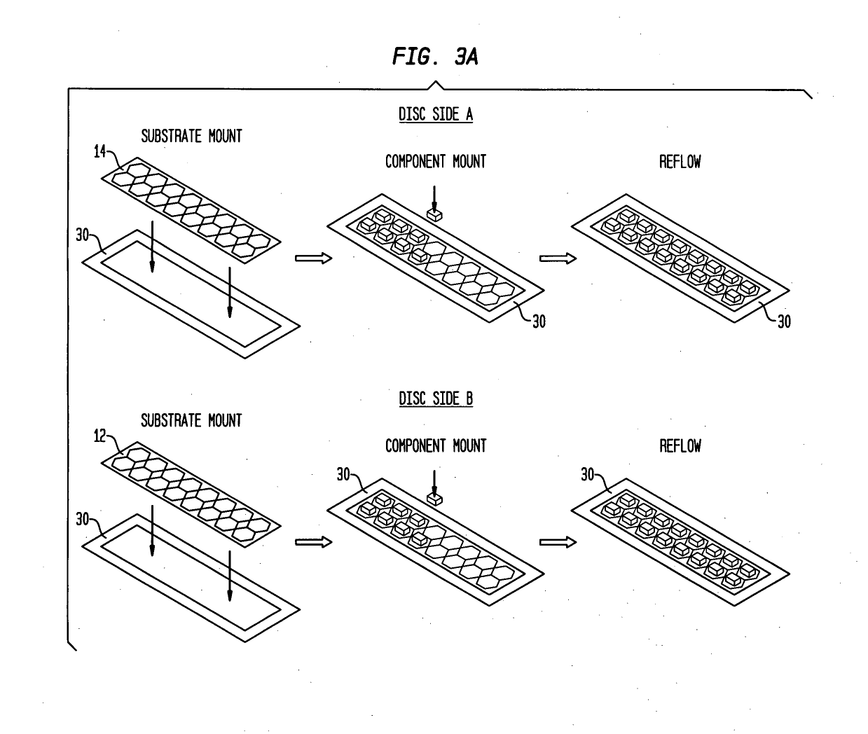

FIGS. 3A-3B depict one example process for manufacturing and assembling assembly 10. While many different techniques may be employed, the assembly process of FIGS. 3A-3B will be discussed herein. Initially, two different sheets of substrate material (which correspond to substrates 12 and 14 respectively) are each preferably mounted to a substrate mount or frame 30. Any suitable mount or frame may be utilized, and such may include top and bottom portions. It is also contemplated to provide pre-mounted substrates. Thereafter, the various electronic components are placed upon the two substrates, along with any spacers 20 or solder balls 22 to be utilized. Thus, components 16 are placed on the sheet of material corresponding to substrate 12 and components 18 are placed on the sheet of substrate material corresponding to substrate 14. This is done in the patterns necessary to allow the above described puzzle-like fit in assembly 10. With the components in place, both mounts 30 are preferably subjected to heat to cause the components to become permanently mounted to the respective sheets of material. All of these aforementioned steps are illustrated in FIG. 3A.

Once each of the mounts 30 includes sheets of substrate material having components mounted thereto, they may be stacked as mentioned above. More particularly, the top surfaces of the sheets of substrate material are sandwiched together and the various components are situated in their puzzle-like fit. Clearly, components 16 and 18 must be initially placed so as to allow such a cooperation between the two sheets of substrate material and their respective components. With the two sheets situated together, both mounts 30 are subjected to more heat to reflow any solder balls 22 that are disposed between the sheets of substrate material. This causes the two sheets to become connected together. Once this is accomplished, an encapsulant may be applied to the space between the two sheets, thus encapsulating the sheets of substrate and components therebetween. Such encapsulant may be applied by utilizing a suitable encapsulation procedure. For example, encapsulation of substrates and components in frames or mounts 30 is taught in U.S. Pat. Nos. 5,766,987, 6,046,076 and 6,329,224, the disclosures of which are hereby incorporated herein by reference.

Subsequent to the connection of the sheets of material together, and the application of encapsulant to same, solder balls or the like may be attached to at least one surface of the assembly, to allow for connection of the assemblies to circuit panels or the like. In addition, the assemblies may be tested and marked, in accordance with known practices. Finally, individual assemblies, like the above discussed assembly 10, may be singulated from the overall assembly. Many different singulation procedures may be utilized, with one such procedure being taught in U.S. Provisional Application No. 60/624,667, the disclosure of which is hereby incorporated herein by reference. Essentially, this procedure involves punching out the individual assemblies 10 from the mounts or frames. Therefore, the above described process yields several assemblies 10 in accordance with the present invention. Depending upon the overall size of the sheets of substrate material utilized, the overall number of assemblies 10 may vary.

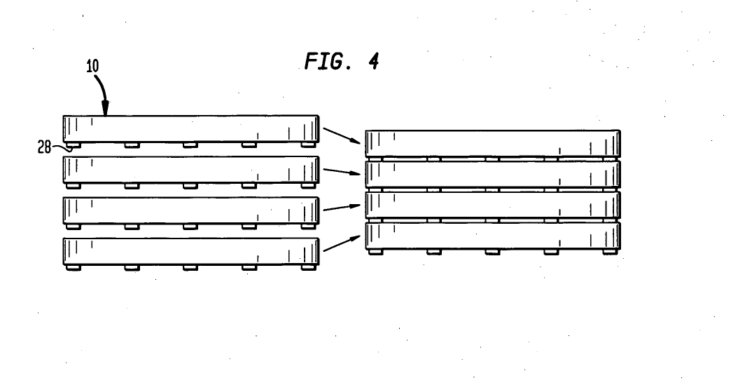

FIG. 5 depicts another embodiment assembly 10′, which includes similar elements to the above described assembly 10. Like elements are labeled with like reference numerals, only employing a “′” indicator. For example, assembly 10′ includes two substrates 12′ and 14′, which are substantially similar to substrates 12 and 14 of assembly 10. However, rather than employing solder balls 20 or the like, substrates 12′ and 14′ of assembly 10′ are connected together via pins 24′. Many different pin designs may be utilized to connect the substrates, and may be affixed thereto by any suitable process.

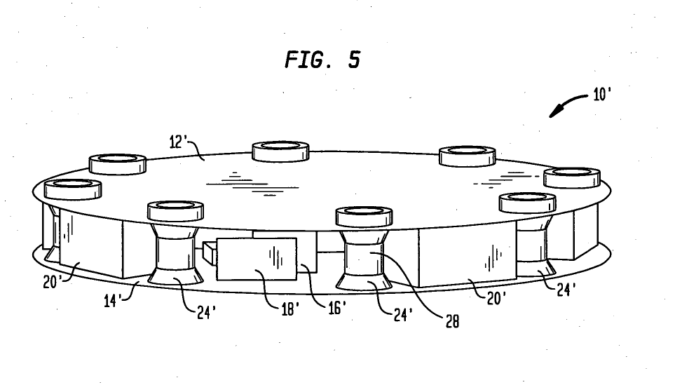

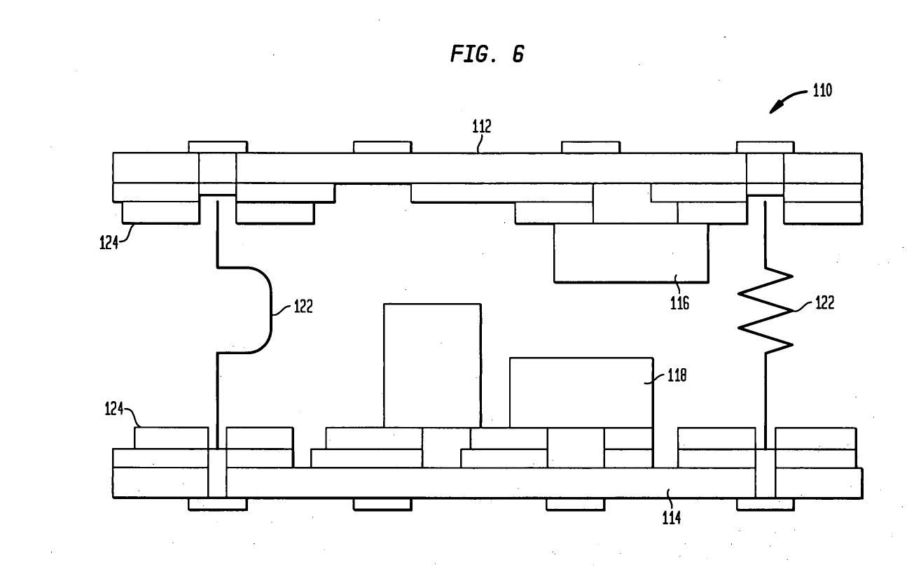

Other modes of attachment of two substrates in packages according to the present invention may be employed. In fact, any suitable method of attaching two substrates may be utilized to create assemblies, such as the above-described assemblies 10 and 10′. FIGS. 6 and 7 depict another embodiment assembly 110, which employs a different connection between two substrates 112 and 114. It is noted that once again, like elements are labeled with like reference numerals, but this time, within the 100-series of numbers. The connection utilized in assembly 110 involves the use of spring loaded electrical contacts 122 between the substrates, as opposed to the above described solder balls 22 and pins 24′. This will be more fully discussed and described below.

As is best shown in FIG. 6, contacts 122 are preferably attached to substrates 112 and 114 prior to encapsulation of assembly 110. In fact, contacts 122 are first preferably attached to one substrate, for example, bottom substrate 114 (see FIG. 6). This connection may be done in any suitable fashion, such as, by solder or adhesive. With contacts 122 connected to substrate 114, substrate 112 is preferably placed over same so that contacts 122 form an electrical connection between the printed circuit boards. It is noted that the placement of the substrates with respect to one another may be dictated by the overall desired thickness of assembly 110, and may be done with the aid of clamps or other support mechanisms. Once the desired placement is achieved, the heretofore unassembled components may be subjected to a reflow process to melt solder 124 disposed on the respective substrates at or near the interconnection with contacts 122. This reflow process preferably causes solder 124 to become situated in the manner shown in FIG. 7, and thereby creates at least one fixed connection between substrates 112 and 114. In this regard, it is noted that more than one contact 122 may be utilized to connect opposing substrates, such as the two shown in FIGS. 6 and 7. Finally, an encapsulant 126 (FIG. 7) may be administered to fill the space between substrates 112 and 114 to form a finished assembly 110. Such material may be administered in accordance with any of the above-discussed methods, as well as those methods discussed in more detail below.

Ultimately, assembly 110 (best shown in FIG. 7) is a solid block of circuitry with some compliance due to contacts 122 and encapsulant 126. Of course, the particular properties of each of these materials dictate this compliance. For example, the more compliant spring contacts 122 and encapsulant 126 are, the more compliant the overall assembly 110 will be. It is contemplated to form contacts 122 out of metallic material suitable for spring-like action, and encapsulant 126 out of similar spring-like material, such as flexible epoxy. The design of assembly 110 preferably does not include any holes in either of substrates 112 and/or 114, as the particular design of contacts 122 do not require such. This may aid in preventing leakage of encapsulant 126 during the assembly process of assembly 110. Depending upon the method employed in adding encapsulant 126, there may no longer exist any apertures for such encapsulant material to escape from. Finally, it is worth noting the contacts 122 may themselves exhibit different constructions. For example, FIGS. 6 and 7 depict several different contact 122 configurations, which may change the spring-like properties of assembly 110 and/or the overall height of assembly 110.

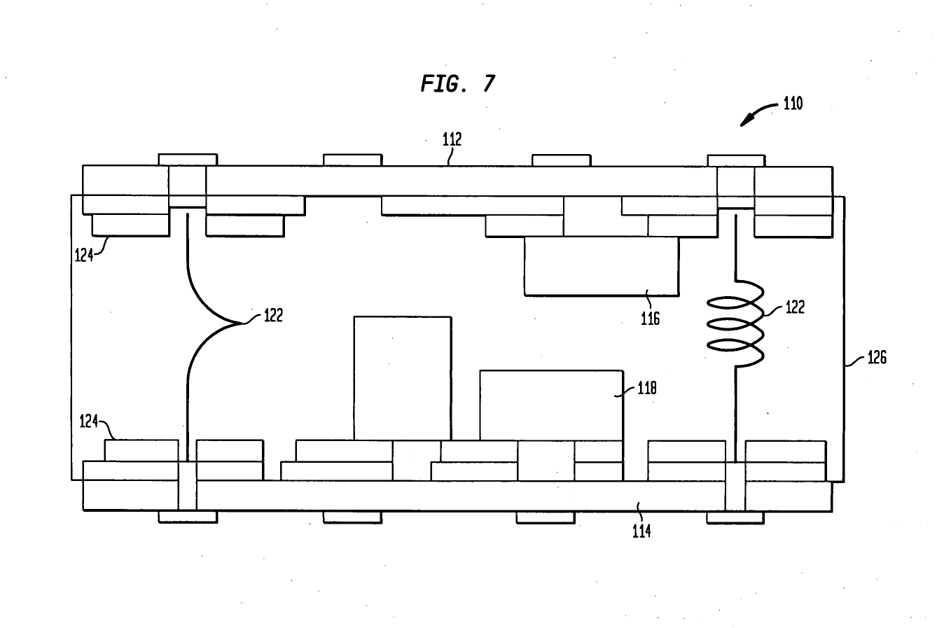

Yet another embodiment assembly 210 is depicted in FIG. 8. Once again, like elements between the assembly shown in FIG. 8 and those described above are labeled with like reference numerals, within the 200-series of numbers. For example, assembly 210 includes opposing substrates 212 and 214, which include components 216 and 218, respectively. In addition, spacers 220 are included for keeping substrates 212 and 214 spaced apart a desired distance. However, unlike any of the above embodiments, assembly 210 includes screws 222 and rivets 224 for connecting the substrates together, both mechanically and electrically. Screws 222 are preferably highly conductive screws which are configured to screw into or otherwise engage highly conductive rivets 224. Examples of suitable materials for the construction of screws 222 and rivets 224 include, but are clearly not limited to, metallic materials such as stainless steel, polymeric materials or the like. Screws 222 also preferably include a head portion 222a and a shank 222b, where head portion 222a extends above substrate 212 and shank 222b is long enough to extend rivets 224 on substrate 214. Shank 222b also preferably includes a threaded portion for cooperating with a like threaded portion 224a in rivet 224. In addition, rivets 224 may include a cupped or depressed area 224b, which allows for the engagement of, for example, head portion 222a during the stacking of multiple assemblies 210.

In the assembly process of assembly 210, substrates 212 and 214 are preferably aligned in a similar fashion to that of the above-described embodiments. However, spacers 220 are preferably employed for properly spacing the substrates from one another, which eliminates that need for clamps or other support mechanisms. Thereafter, screws 222 may be inserted through substrate 212 and ultimately into engagement with rivets 224. Further tightening of screws 222 preferably pulls the substrates towards one another and against spacers 220. Finally, an encapsulant (not shown) may be applied to the assembly like in the above-discussed embodiments. As will be discussed more fully below, such encapsulation process may involve injecting material through holes or apertures (shown as elements 226 in FIG. 8) in spacers 220. It is noted that the design taught in this embodiment prevents the need for clamps or other external fixation means for the substrates, as well as avoids the need for heating or otherwise reflowing the assembly to provide interconnections between substrates 212 and 214. Assembly 210 is generally a mechanically coupled assembly which may be manipulated through the tightening and loosing of screws 222.

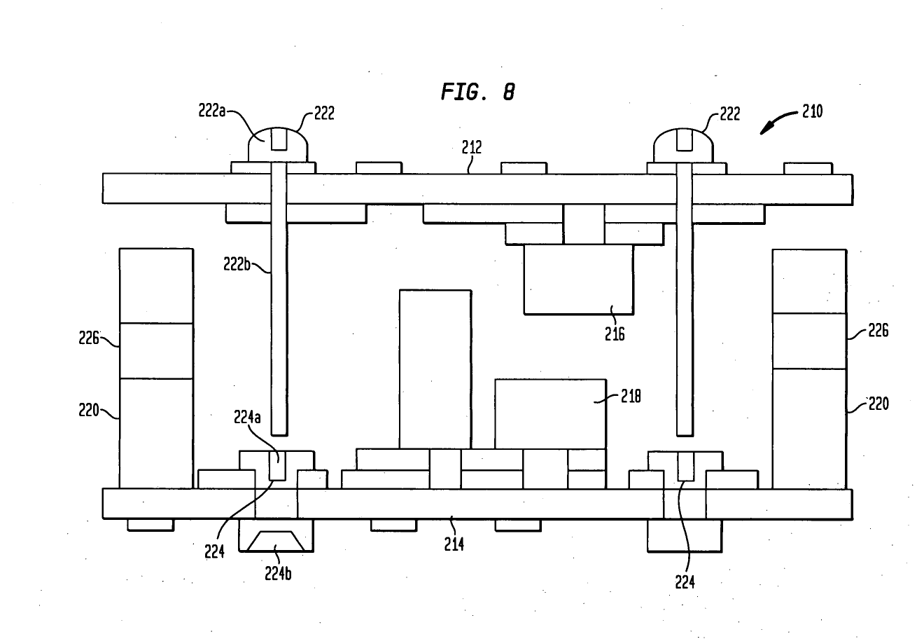

FIG. 9 depicts still another embodiment assembly 310. As with all of the embodiments discussed hereto, like elements will be referred to with like reference numerals, but this time within the 300-series of numbers. In this regard, assembly 310 includes substrates 312 and 314 which include components 316 and 318 respectively, and are spaced apart by spacers 320. However, in this embodiment, substrates 312 and 314 are connected, both mechanically and electrically, by loops of wire 322. More particularly, loops 322 connect contact pads 324 on substrate 312 with contact pads 326 on substrate 314, thereby providing for electrical interconnection between the substrates and the respective components located on each. Once again, as is the case in certain of the above-describe connection means, loops 322 are preferably initially connected with one substrate, in this case, bottom substrate 314. The loops preferably extend above the surface of substrate 314 such that when substrate 312 is brought into its final position, loops 322 make contact with contact pads 324 located thereon. Preferably, the stiffness of the wire of loops 322 acts as a spring to hold the wire in contact with pad 324. On the other hand, loop 322 may be connected with pad 326 of substrate 314 in any suitable fashion, such as through the use of solder.

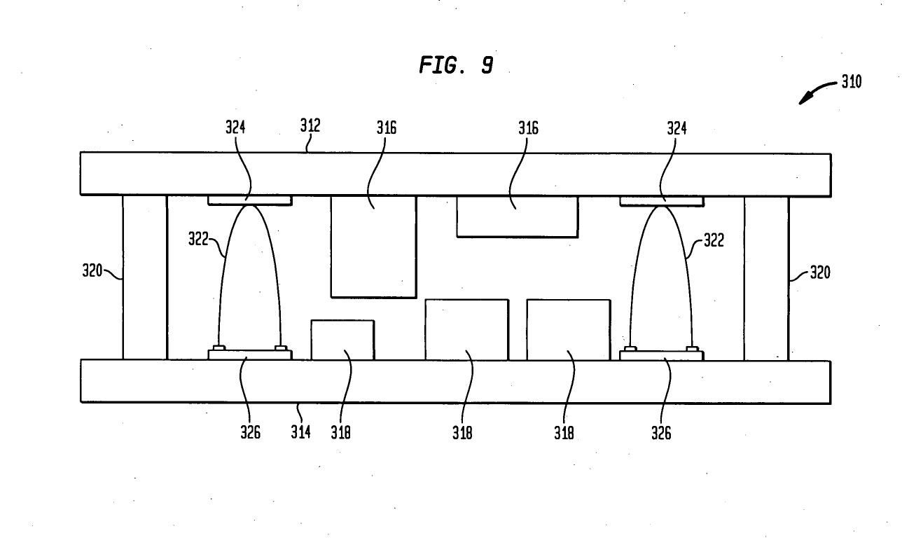

FIGS. 10a-g depict certain contemplated variations of the basic wire loop interconnection shown in FIG. 9. Other configurations are also envisioned, and the present application is not specifically limited to that which is shown. Those of ordinary skill in the art would readily recognize such additional variations. Nonetheless, FIGS. 10a-g depict several possible configurations which may be employed in assembly 310. FIG. 10a, for example, shows single loops which are formed on each of contact pads 324 and 326 of substrates 312 and 314 respectively. When the substrates are brought together in their final location, both loops 322 preferably deform and hold each other in contact. It is noted that both loops 322 may be preformed such that they are more likely to remain in contact after assembly, and such connection can be improved depending upon the resiliency of the wire material utilized in forming loops 322. FIG. 10b is similar to that which is shown in FIG. 10a, with multiple loops being present on both top and bottom contact pads 324 and 326.

The configuration shown in FIG. 10c depicts a loop 322 on bottom pad 326 and one or more loops 322 on top pad 324, where the latter loops capture the former loop upon assembly. This may act to maintain contact after an encapsulant is introduced between substrates 312 and 314. Essentially, this configuration aids in keeping the loops together even in the face of certain side forces which may be caused during encapsulation, and which may otherwise move the loops outs of contact with one another or pad 324. FIG. 10d depicts a single loop 322 on bottom substrate 314 being forced against multiple loops 322 of top substrate 312. The loops on the top are preferably offset on either side of the bottom loop so as to form a channel for it to fit into. FIG. 10e depicts multiple loops on both top and bottom substrates 312 and 314 which are preferably parallel to each other. The spacing of the loops is also approximately the same as the individual wire diameters, thereby forcing the various loops to mesh. FIG. 10f shows that, in addition to being attached to bottom substrate 314, loops may be anchored to a top pad 324 of top substrate 312. This may be done by many different processes, such as through the use of solder or another conductive adhesive. Finally, FIG. 10g depicts the use of a ball mounted to, or formed integral with, the end of a bottom wire loop, which is capture between parallel top loops. Such design may allow for the required interconnection without the need for specific tolerances between the various loops.

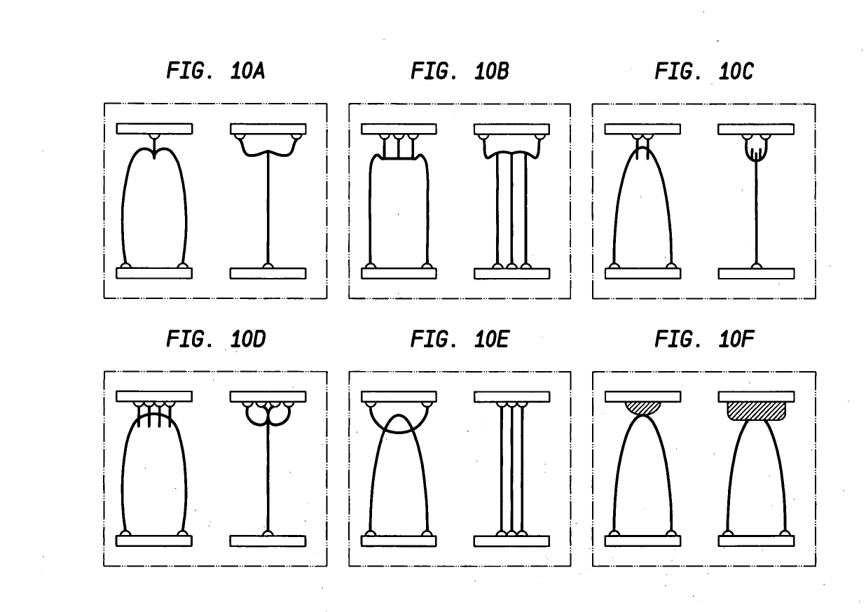

A further embodiment assembly 410 is depicted in FIGS. 11a-c. In line with the above, like elements among the various embodiments are labeled with like reference numerals, but this time within the 400-series of numbers. For example, assembly 410 includes substrates 412 and 414, each having components 416 and 418, respectively. However, in this embodiment, assembly 410 is initially assembled without any interconnections between substrates 412 and 414. In fact, assembly 410 is even encapsulated (with a suitable material as described above) without such interconnections (best shown in FIG. 11a). After this encapsulation procedure, assembly 410 is preferably drilled to create vias 422 which align conductive traces or other connections between the substrates. Assembly 410 subsequent to this drilling step is shown in FIG. 11b. It is noted that this drilling procedure may be accomplished through any capable procedure, such as, mechanical drilling or laser drilling. Thereafter, vias 422 are preferably plated with a conductive material to form electrical interconnections between the substrates (shown in FIG. 11c).

In accordance with this embodiment, assembly 410 is created with the same benefits as those assembly embodiments described above. In addition, the method employed to create assembly 410 may lower costs associated with manufacturing, thereby lowering the cost of the overall assembly. In this embodiment, problems associated with reflow of the assembly prior to final encapsulation are avoided, as no reflow is necessary. Rather, interconnections are formed subsequent to the encapsulation process. It is noted that various materials may be utilized in the plating of vias 422, preferably electrically conductive materials such as metallic materials or the like.

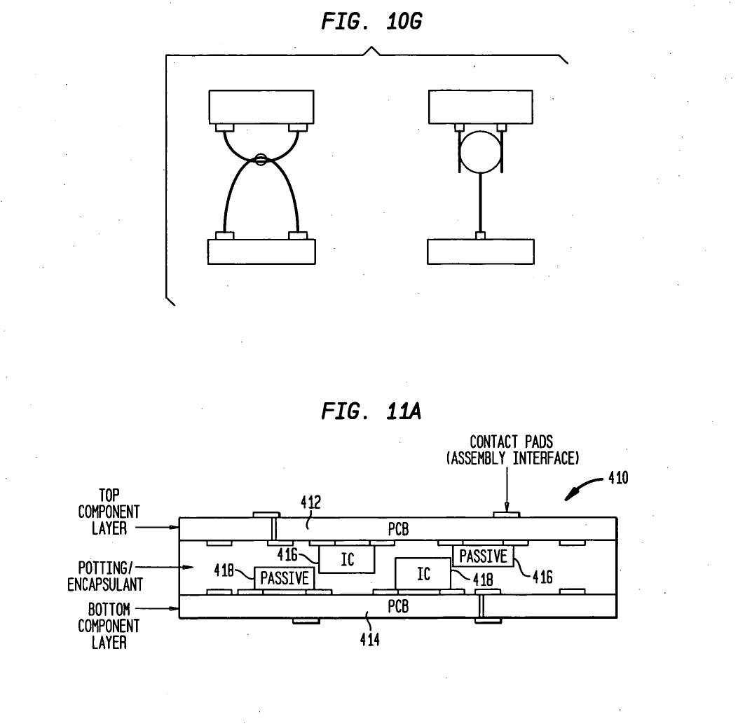

Although not specifically mentioned above in relation to each of the foregoing embodiments, it is to be understood that more than two substrates may be provided in a single assembly. For example, as is shown in FIG. 12, assembly 510 includes three substrates 512, 513 and 514. Once again, like elements between those included in assembly 510 and the above-discussed embodiments are labeled with like reference numerals, but this time within the 500-series of numbers. For example, substrates 512 and 514 include components 516 and 518 mounted to one their respective surfaces, while substrate 513 preferably includes components 517 mounted to both of its surfaces. In addition, assembly 510 employs shoulder pins 522 which set the mechanical distance between the substrates and makes electrical connections between same. Preferably, shoulder pins 522 are soldered in place, along with other components, on bottom substrate 514. Central substrate 513 and top substrate 512 are preferably placed over pins 522 during an assembly process and the various substrates are secured via a reflow process. Thereafter, an encapsulant or the like is injected between the substrates, in a similar fashion with that described above, and to be described below. In the end, assembly 510 becomes a single package with electrical connections disposed at its top and bottom portions, in a similar fashion to the other embodiment assemblies of the present invention.

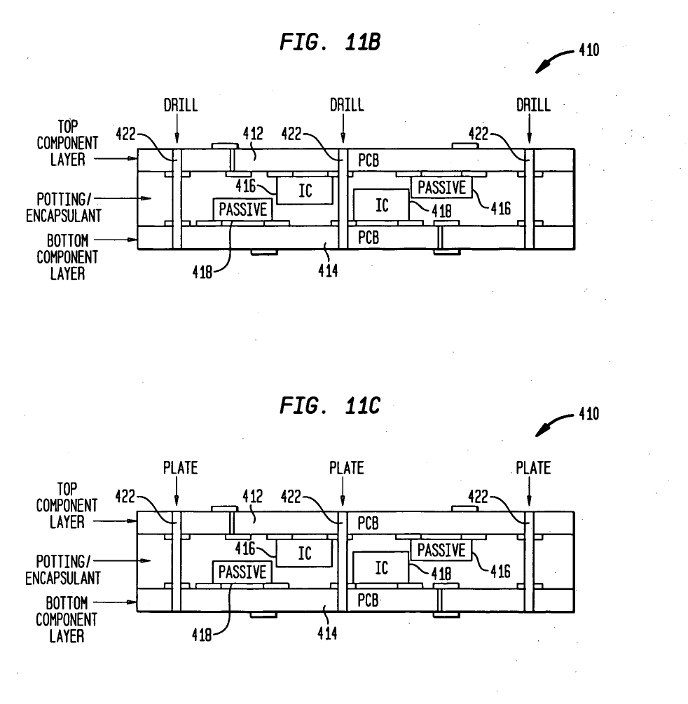

In addition to several variations relating to the interconnection between opposed substrates in accordance with assemblies of the present invention, several methods of performing at least certain steps in the manufacturing processes of the various assemblies are now disclosed. For example, FIG. 13 depicts an assembly 610 similar in construction to assembly 110 originally shown in FIG. 6 and described above. In fact, assembly 610 includes identical components (labeled with reference numerals within the 600-series of numbers). However, assembly 610 employs the use of one or more spacer blocks 620 during its construction. These blocks are similar to those depicted in FIG. 8, in relation to assembly 210, and are not only useful for properly spacing apart substrates 612 and 614, but also during the encapsulation process. A discussion of this process and the specific use of blocks 620 follows below.

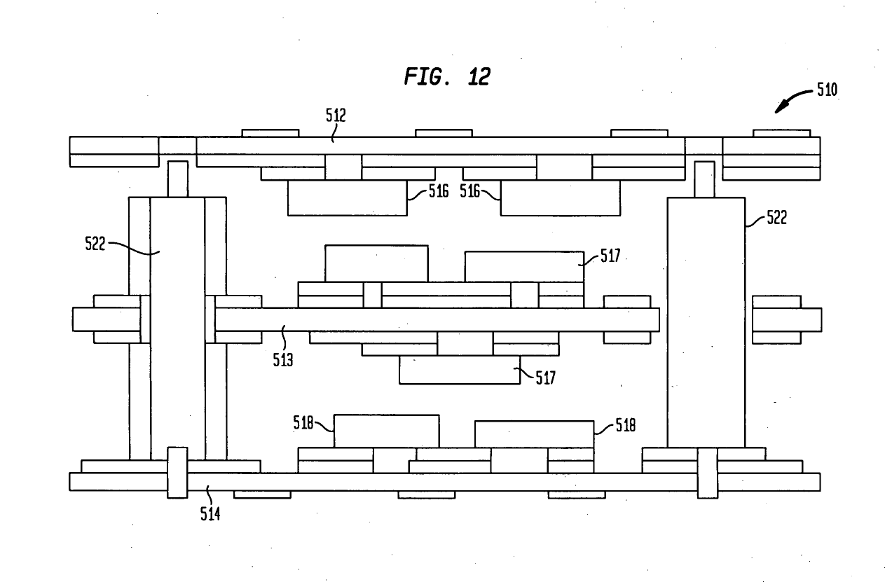

FIG. 14 depicts a plurality of blocks 620 organized as one integral larger block 630. The outlines of certain blocks 620 are shown in FIG. 14 by broken lines, and although shown as substantially squares blocks, blocks 620 may be any shape (e.g., circular or the like). As is further shown in the figure, block 630 is essentially a solid structure having a plurality of apertures 632, which substrates 612 and 614 are preferably aligned and in which components 616 and 618 may be disposed. In this regard, it is noted that larger sheets of substrate material may initially be aligned with block 630. In addition, as is best shown in FIG. 13, block 630 also preferably defines encapsulant passages 626 therethrough. These are important in the encapsulant procedure, as is discussed more fully below. In a construction process, either individual substrates 612 and 614 or continuous sheets of substrate material are placed on top and bottom surfaces of block 630. This is done so that components (like components 616 and 618) located on each substrate are aligned with apertures 632 and ultimately disposed therein, and so that at least a portion of the substrate extends beyond aperture 632 and into contact with either the solid top or bottom surface of block 630. In this position, substrates 612 and 614, or solid sheets including same, are preferably situated in a proper vertical relationship with respect to one another. Of course, this is dependent upon the thickness of block 630, so a properly sized block should be selected.

Once in the above position, the entire assembly 610 may be subjected to a reflow process in order to create the connections between the substrates and contacts 622. In other embodiments, such assemblies may not require this reflow, as will be discussed more fully below. With the connections made between substrates 612 and 614, an encapsulant may be injected through passages 626 (there may be more than one such passage) and between the substrates. This preferably creates a solid block of circuitry with some compliance due to the spring contacts 622 and the preferably flexible epoxy encapsulant being utilized. Finally, the individual assemblies 610 may be singulated or otherwise separated from the overall assembly. This may be accomplished by any suitable procedure, including the above-noted processes and/or cutting out the individual assemblies with a saw or router. It is noted that this cutting process may or may not include cutting around the individual spacer blocks 620, so that the final assembly 610 may or may not include such block portion in its final form.

It is noted that the above described process of forming individual assemblies in accordance with the present invention may be utilized in creating any of the other embodiment assemblies discussed herein. However, such may include fewer, less or even different steps in the construction process. For example, the assemblies shown in FIGS. 8 and 9 (as well as the variations of assembly 310 shown in FIGS. 10a-g) may be created utilizing a block 630. In fact, assembly 210 (FIG. 8) depicts such assembly with an individual block 620. Of course, the design of assembly 210 does not require the reflow step needed in constructing assembly 610. It is noted that assembly 410, as shown in FIG. 11a, can be initially constructed utilizing a similar process to that of assembly 610. Thereafter, such assembly could be subjected to the necessary drilling and plating steps discussed above. Finally, it is also possible to utilize two blocks 630 in the construction of assembly 510, as shown in FIG. 12. Those of ordinary skill in the art would readily recognize that such may involve simply disposing like blocks between each set of substrates, and thereafter encapsulating same.

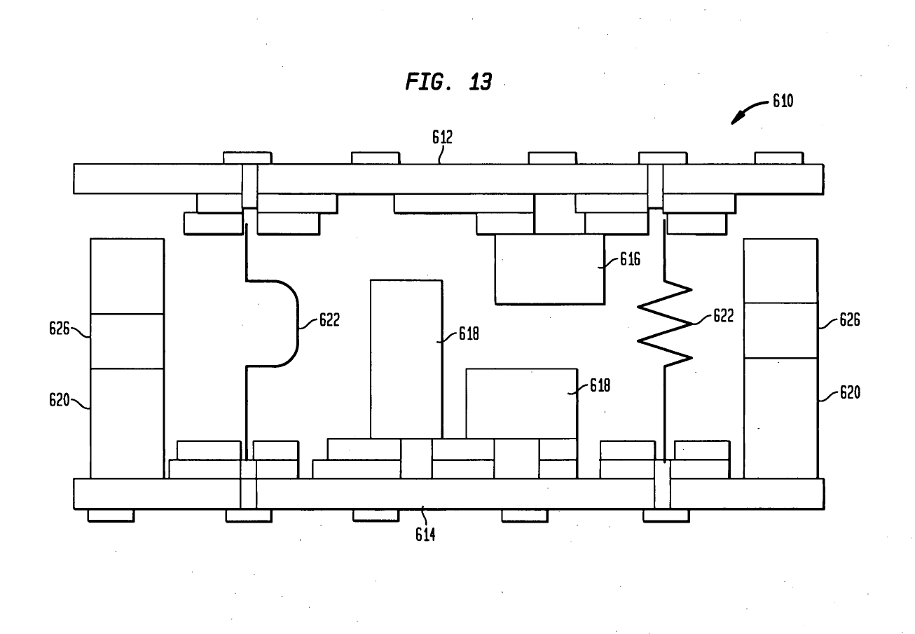

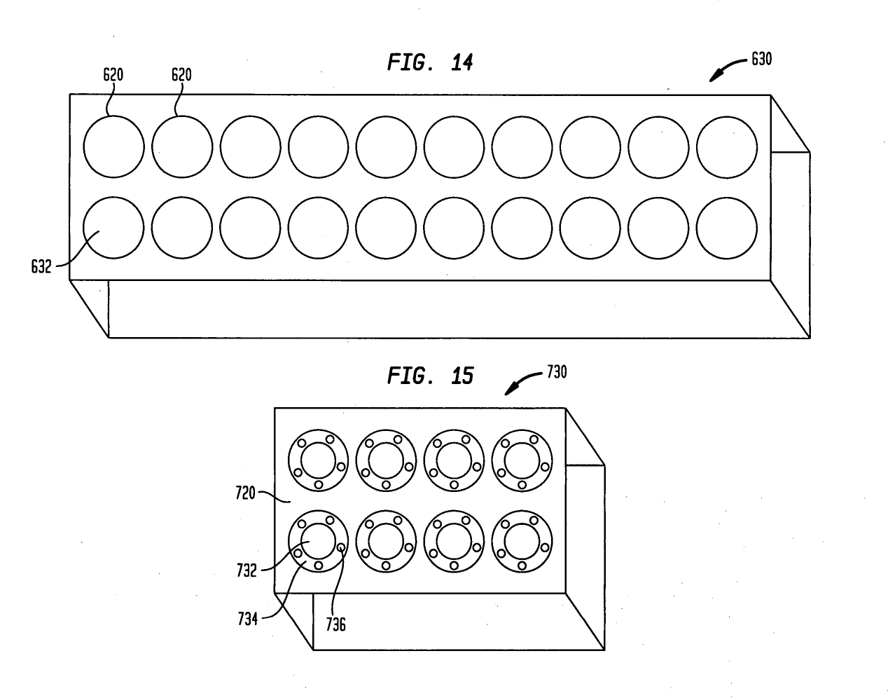

FIGS. 15-18 depict assemblies utilizing different variations on the above-discussed spacer block. Essentially, as is shown in such figures, it is contemplated to provide spacer blocks which themselves include electrical contacts in accordance with the present invention. More particularly, as is shown in FIG. 15, a large block 730 may be provided, which is capable of being used to construct a plurality of assemblies. Block 730 preferably includes a plurality of apertures 732, which can be broken into several smaller spacer blocks 720 (shown in FIG. 16). This is not unlike block 630 of the previously discussed embodiment, and is preferably utilized to form an assembly 710 with similar elements as the above-discussed assemblies. However, each aperture 732 of block 730 is preferably defined by a circular section 734 of different material (e.g.—FR4) than the remainder of block 730, which includes one or more vias 736 capable of providing an electrical contact. Such vias may be constructed of almost any type of conductive material, such as, copper. The amount of apertures 732 and circular section 734 on each block 730 can vary depending upon the amount of individual assemblies desired, as can the number of vias 736 extending through sections 734.

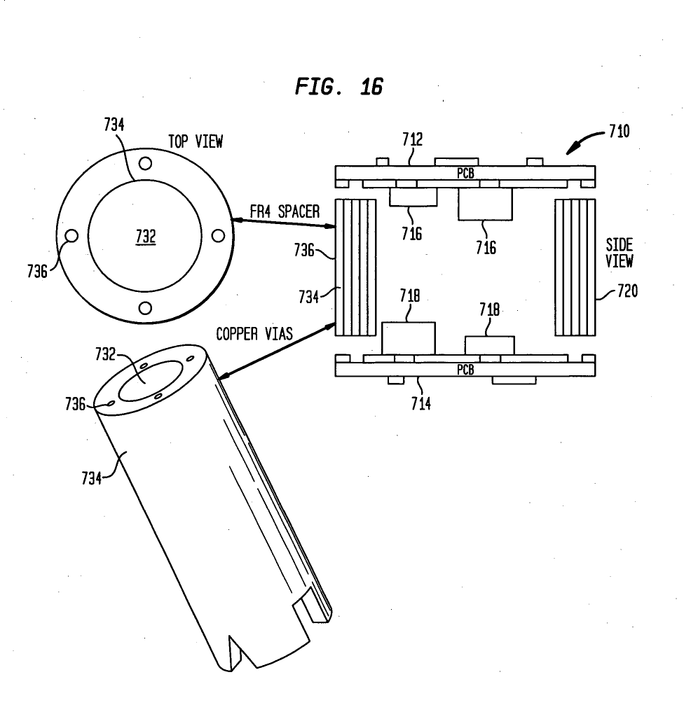

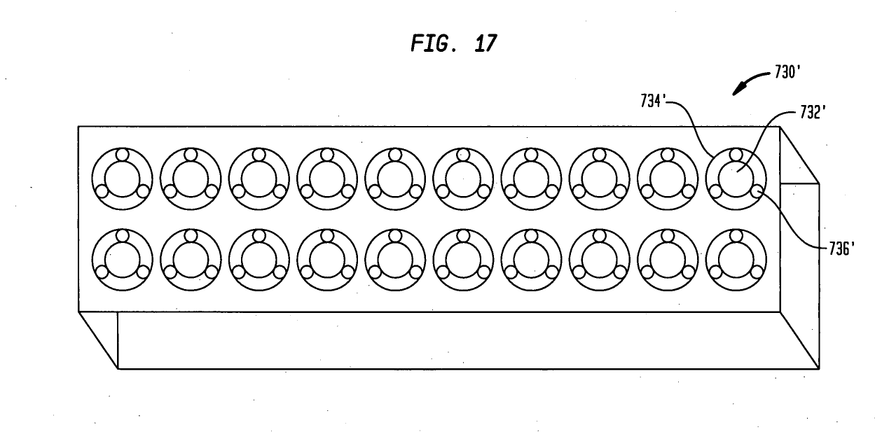

A similar and separate embodiment assembly 710′ and block 730′ is shown in FIGS. 17 and 18. Essentially, the difference between the embodiment shown in FIGS. 15 and 16, and that shown in FIGS. 17 and 18 is the number of vias 736, 736′ included in each circular section 734, 734′. The design shown in the latter figures preferably includes less vias 736′ and may exhibit more flexible properties.

Blocks 730 and 730′ may be utilized in substantially the same fashion as the previously discussed block 630. Of course, during the construction of assembly 710, 710′, the step of connecting together substrates 712, 712′ and 714, 714′ is accomplished during placement of the block. A reflow step or the like still may be required to fixably connect block 730, 730′ with the substrates, by solder or the like, but the utilization of separate contacts is not needed. Ultimately, individual assemblies 710, 710′ may be singulated as long as at least the vias 736, 736′ remain in contact between the substrates. This means that portions of circular sections 734, 734′ may be cut away or otherwise removed. Of course, the entire section may remain in a finished assembly. The spacer blocks in accordance with this embodiment essentially provide for position control of the substrates with respect to one another, an electrical path between the substrates, and the capability of directing and encompassing encapsulant flow, in a similar fashion as discussed above (e.g.—through encapsulant passages). Clearly, this provides a highly useful assembly and beneficial process for manufacturing same.

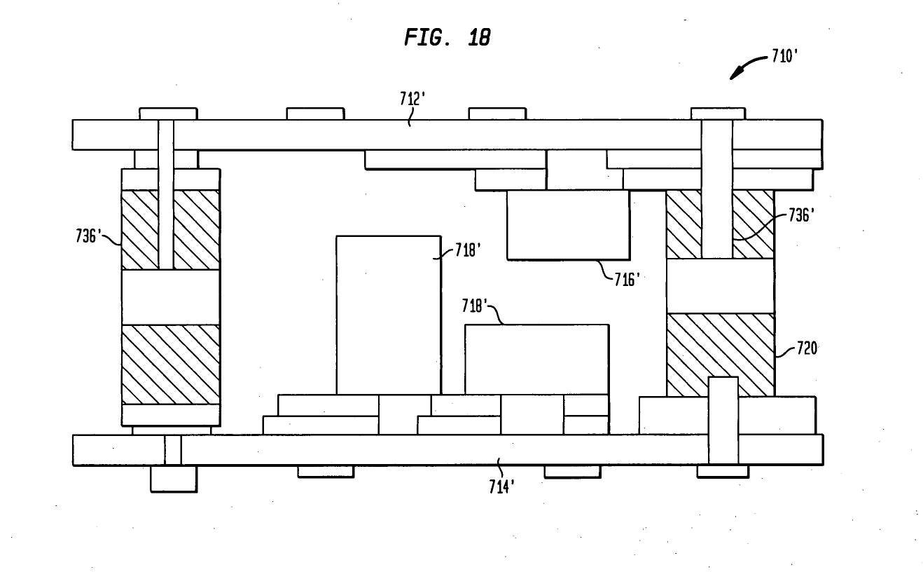

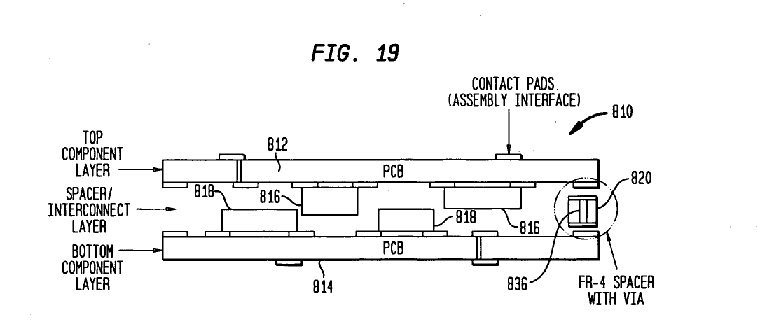

FIG. 19 depicts yet another embodiment assembly 810, which also employs spacer blocks 820 with vias 836 therein. Once again, like elements are identified with like reference numerals, within the 800-series of numbers. For example, vias 836 ultimately connect substrates 812 and 814 of assembly 810. Likewise, construction of assembly 810 is similar to that of assemblies 610 and 710, and may be accomplished with any of the variations described heretofore. However, as is shown more fully in FIGS. 20-22, assembly 810 may utilize different design large blocks 830, 830′ and 830″ in constructing an assembly which includes a spacer block 820, 820′ or 820″. Essentially, as will be more fully discussed below, each of these blocks preferably aids in providing an encapsulant passage 854, 854′ and 854″ for use during construction of a plurality of assemblies 810.

As has been discussed above, a typical construction process for one of the assemblies discussed in accordance with the present invention usually involves utilizing larger sheets of substrate materials and spacer material, and thereafter cutting or otherwise singulating the individual assemblies. FIGS. 20-22 depict examples in which two individual assemblies are constructed. Of course, similar structures and method steps may be followed in order to create more than just two assemblies. As is shown in FIG. 20, a larger sheet of substrate material 811 is provided and includes two substrates 812, and a larger sheet of substrate material 813 is provided and includes two substrates 814. Components 816 and 818 are also provided on the respective material sheets 811 and 813, preferably only in the area defining substrates 812 and 814. A larger spacer block 830 is also provided, and preferably includes two spacer blocks 820 with vias 836 for cooperation with the aforementioned substrates 812 and 814 in the fully constructed assembly 810. In addition, larger block 830 also preferably includes passages 854 for directing an encapsulant during an encapsulation procedure. Such passages preferably cooperate with input and output ports 850 located on sheet 811.

During a construction process of assembly 810, block 830 is first placed on sheet 813. Thereafter, sheet 811 may be placed upon block 830. Vias 836 preferably create electrical connections between the different substrates. Once in this position, the entire assembly may be subjected to a reflow process, as is set forth above, in order to fixably connect the components together. Subsequent to the reflow process (if one is necessary), an encapsulant may be introduced through input port 850 on sheet 811. Preferably, the encapsulant is then directed through passages 854 of block 830 and into a position between what ultimately becomes substrates 812 and 814. Upon the injection of a sufficient amount of encapsulant, overflow preferably exits through output port 852. At this point, the individual assemblies may be singulated (possibly after a sufficient curing period) along the broken lines depicted in FIG. 20, in order to form individual assemblies 810.

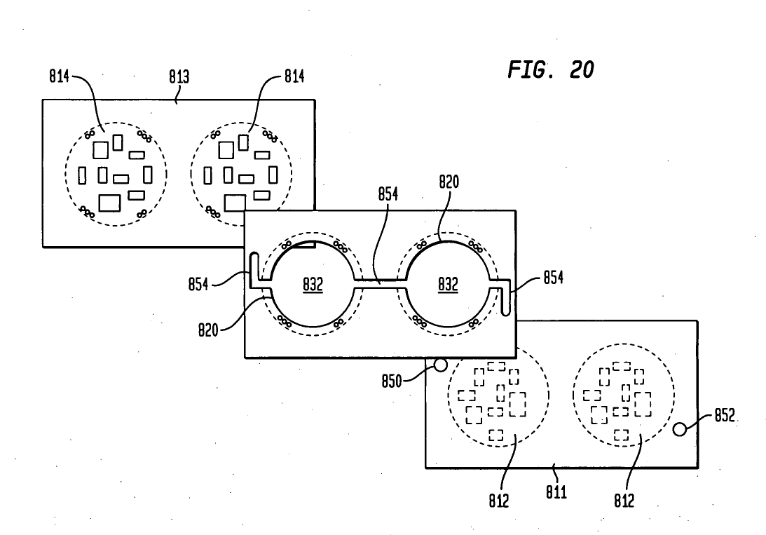

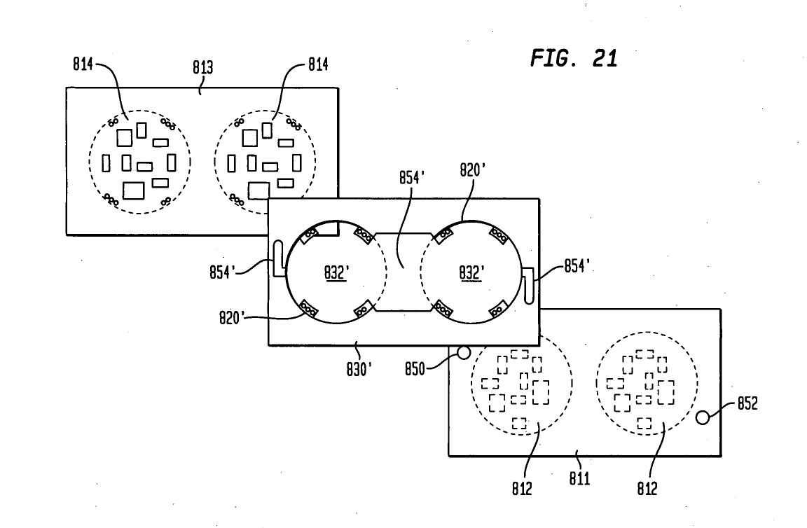

FIGS. 21 and 22 depict variations on the larger spacer block 830′ and 830″. In addition to providing for differently configured spacer blocks 820′ and 820″, than that of spacer block 820, such larger blocks also provide for different passages 854′ and 854″. For example, block 830′ includes passage 854′ with a relatively wider central portion, while block 830″ includes a passage 854″ with multiple paths. Other variations of the larger spacer blocks, as well as their respective passages, would be apparent to those of ordinary skill in the art. These different embodiment blocks may allow for easier or faster encapsulation of the assemblies.

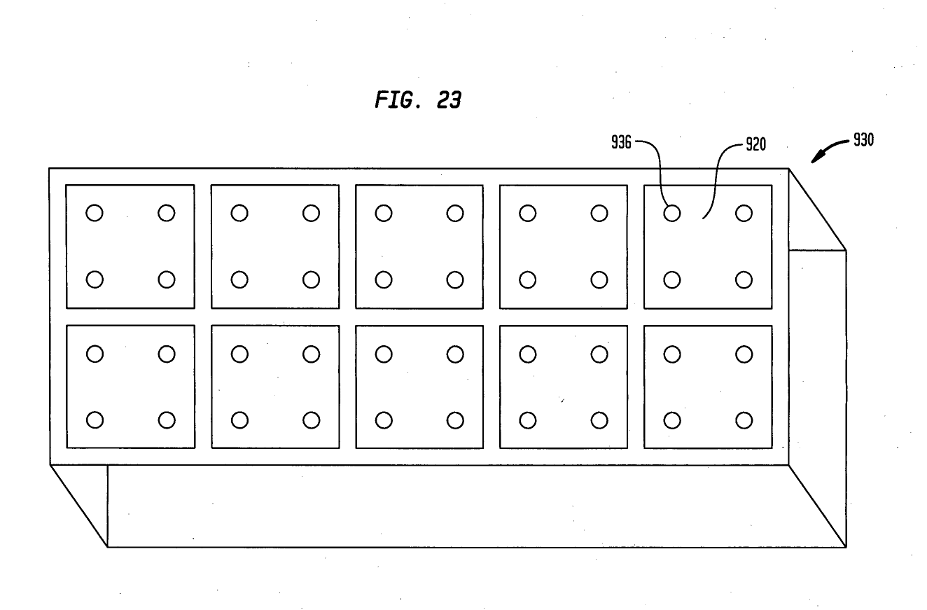

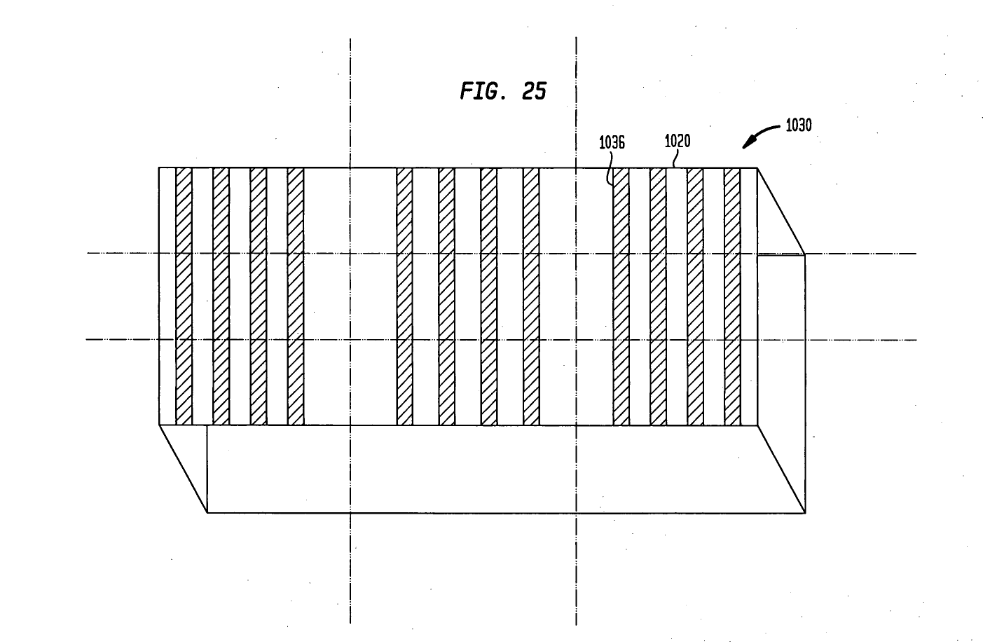

FIGS. 24 and 26 depict assemblies 910 and 1010, respectively, which also employ spacer blocks with vias, in a similar fashion to that of assemblies 710, 710′ and 810. However, rather than utilizing a ring shaped spacer block, or an otherwise enclosed block, assemblies 910 and 1010 utilize individualized blocks (920 and 1020 respectively) for placement between their substrates. Each block 920, 1020 preferably includes vias or other connections 936, 1036 which allows for connection of the respective substrates. It is noted that any of the spacer blocks, or substrates for that matter, which have been discussed above may be of any shape and or size in accordance with the present invention.

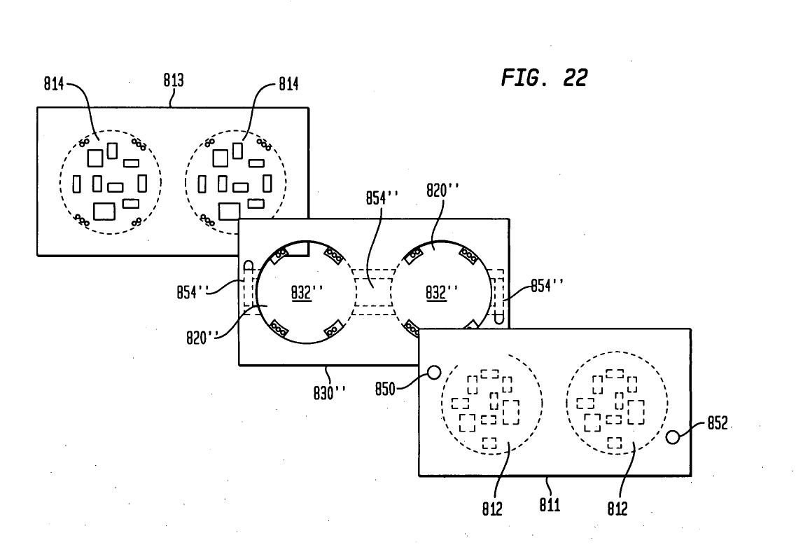

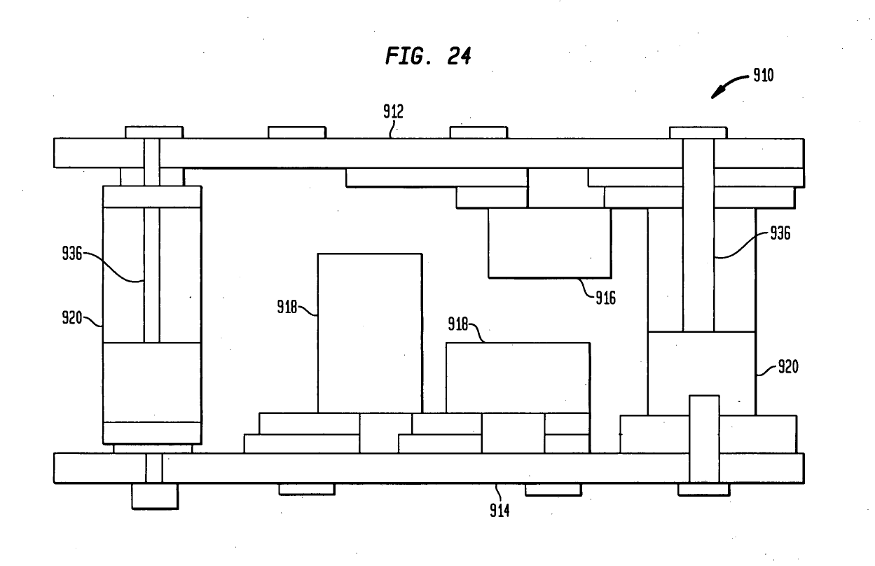

As is shown in FIGS. 23 and 25, larger blocks 930 and 1030 are provided and thereafter singulated to provide a plurality of individual blocks 920 and 1020. Essentially, the different between blocks 930 and 1030 is the particular via 936, 1036 structure employed therein. While block 930 includes a plurality of blocks 920 with vias 936 similar to those discussed above in relation to assemblies 710, 710′ and 810, block 1030 includes a plurality of blocks 1020 with traces 1036 on at least one side. Nonetheless, blocks 920 and 1020 provide the same interconnection function desired in the finished assemblies. Of course other configurations for such blocks could also be employed. FIGS. 23 and 25 also depict proposed singulation lines for cutting along to create the individual blocks. These can also vary depending upon the particular larger block design and the desired spacer block.

The construction of assemblies 910 and 1010 preferably follows along with that of the other assemblies. However, rather than needing to ensure the placement of the substrates, and their respective components, within a hole of the respective blocks, individual blocks are merely placed between the top and bottom substrates of the assembly being constructed. This process lends itself well to the creation of individual assemblies, as opposed to the mass assembly constructions discussed above. Of course, individual blocks 920 and 1020 could also be placed in proper positions between larger substrate sheets, and thereafter individual assemblies could be singulated. Finally, it is worth noting that a reflow step may be important in the construction of assemblies 920 and 1020. FIG. 26 depicts the connection between substrates 1012 and 1014 by spacer block 1020 before such a reflow process (left side), and the similar connection subsequent to reflow.

The above-discussed assembly embodiments provide chip packages which are very reliable and useful in certain environments. For example, most, if not all, of the above assemblies are suitable for use in testing munitions, such as artillery shells. In addition, it is noted that more than one of the assemblies discussed above may be stacked on top of one another in configurations known as or similar to daisy chains. In this regard, it is to be understood that any of such assemblies may be provided with one or more connections on either its top or bottom surface, or even both. Such connections may be situated in any configuration, and can be made specifically to match up with other like assemblies. One example of such connections are simple solder connections that may require a reflow process to cause the adjacent assemblies to be fixable connected to one another. Similarly, other connections types may be implemented, such as wire connections, plugs or the like.

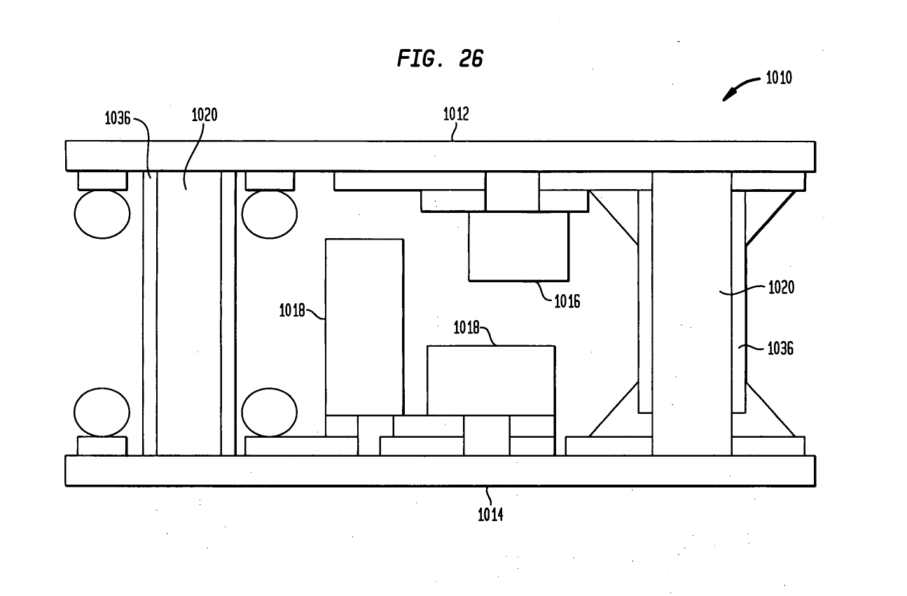

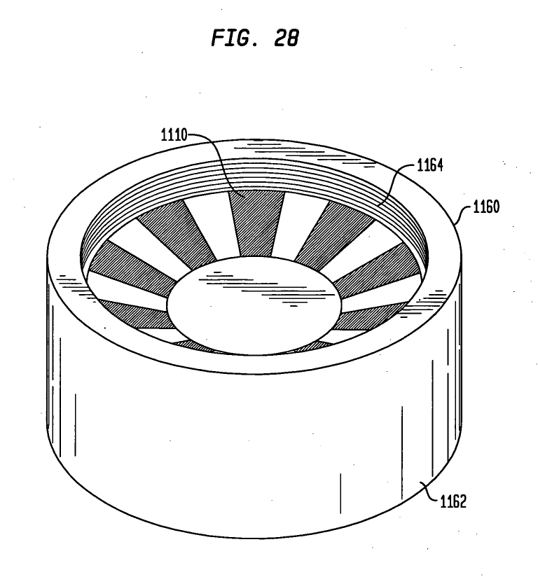

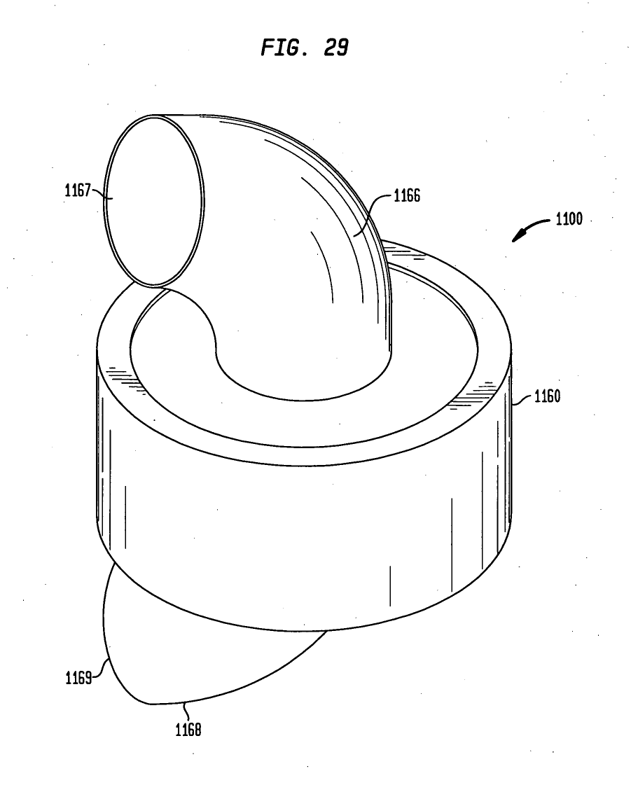

However, some of the above external connections may suffer from weakness limitations. For example, a solder connection may only provide a connection capable of withstanding so much force. Use in munitions research may require stronger connections. FIGS. 27-31 depict a compact and rugged system 1100 for stacking a plurality of threaded assemblies 1110. Essentially, system 1100 creates a mechanical connection/contact between the various assemblies 1110, rather than solder joints. Such connection minimizes the loading across same. Preferably, as will be discussed more fully below, system 1100 is self-loading with no external fasteners being required. Finally, system 1100 is preferably very flexible with individual assemblies and other components being capable of being swapped very easily.

As is best shown in FIG. 27, each assembly 1110 is preferably circular shaped and preferably includes top and bottom surfaces 1112 and 1114, respectively, with a plurality of contacts 1140 being distributed axially on both surfaces. Such contacts preferably extend in both the axial and circumferential directions, with the circumferential extension being substantially greater so as to aid in the connection of multiple assemblies 1110. In addition, assembly 1100 includes threads 1142 extending circumferentially around its side. It is noted that such an assembly may be made in accordance with any of the above-discussed construction methods, with the additional step of creating threads 1142 during singulation of each assembly or thereafter. Such threads could be created through a molding process which would allow each individual assembly 1110 to be screwed out of the mold upon curing of the material utilized in the device. It is also possible to provide the package as a donut-shaped component in which one or more of the above-discussed assembly embodiments could be placed. In this regard, the assembly or assemblies could be placed in a center portion of the substrate and could be overmolded with a suitable material to hold such in place and make top and bottom surfaces 1112 and 1114 flush. Of course connections between the individual assemblies and contacts 1140 must be made, for example, through wires or the like.

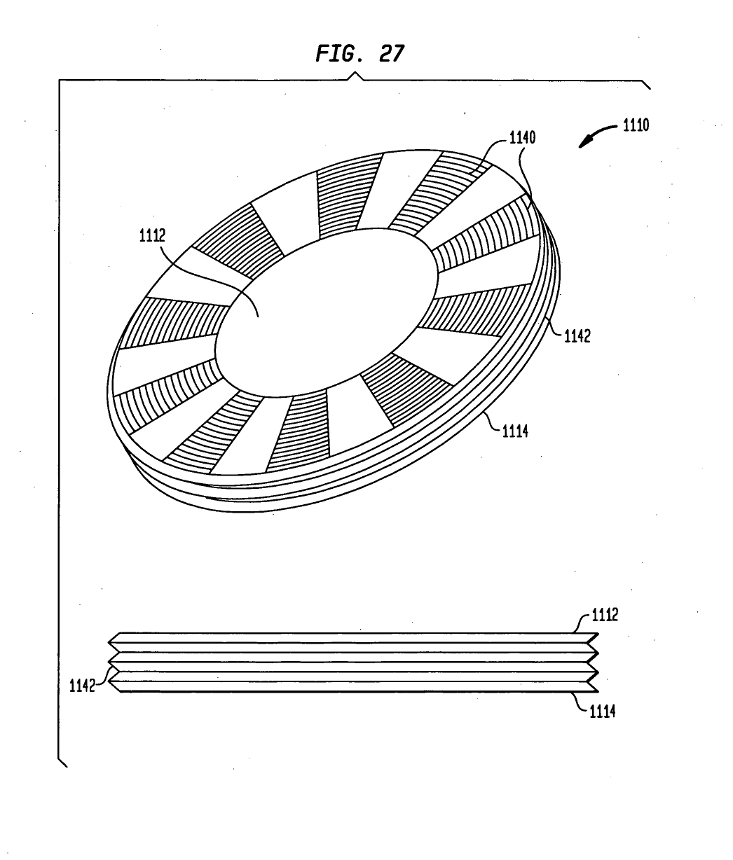

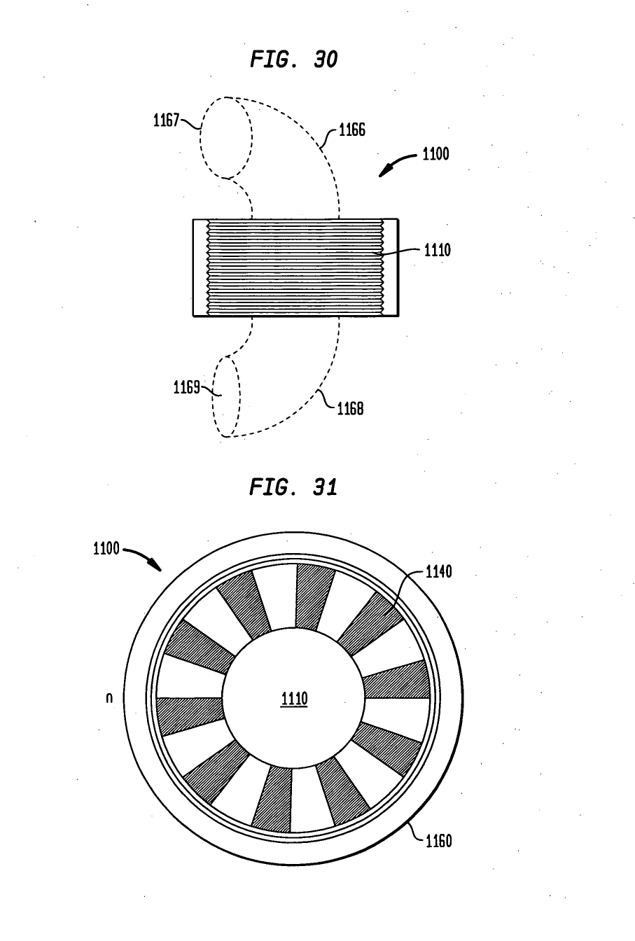

A shell 1160 may also be provided for housing a plurality of assemblies 1110. Such shell is also preferably circular shaped (or at least like shaped to that of assembly 1110) and includes a body 1162 with internal threads 1164. Preferably, shell 1160 is constructed of a stretchable and tough material such as certain polymer materials. FIGS. 28-31 depict shell 1160 and its cooperation with assembly 1110. Essentially, each assembly 1110 is screwed into shell 1160 such that each assembly is over tightened and thereby forced against other adjacent assemblies. This preferably causes the contacts 1140 to be held together (shown in FIG. 31), and may result in the deformation of shell 1160. Lids 1166 and 1168 may thereafter be placed on the top and bottom of shell 1160. Preferably these lids 1166 and 1168 also include cable connectors 1167 and 1169, respectively, or the like for allowing system 1100 to be connected to an outside device. Overall, system 1100 provides for high contact force among the various assemblies 1110, as well as an easily modified system allowing for each swapping of assemblies or other components.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A chip assembly comprising:
a first unit including a first substrate and one or more first electronic components mounted to the first substrate;
a second unit including a second substrate and one or more second electronic components mounted to the second substrate; and
at least one connection between the first and second substrates,
wherein said first and second units are connected together so that the first electronic components project from the first substrate toward the second substrate and the second electronic components project from the second substrate toward the first substrate, at least some of said first electronic components extending between at least some of said second electronic components.

2. The chip assembly according to claim 1, wherein a distance between the first and second substrates is less than the total height of one said first electronic component and one said second electronic component.

3. The chip assembly according to claim 1, further comprising an encapsulant disposed between said first and second units.

4. The chip assembly according to claim 1, wherein the at least one connection includes at least one spring loaded contact.

5. The chip assembly according to claim 1, wherein the at least one connection includes at least one screw and rivet.

6. The chip assembly according to claim 1, wherein the at least one connection includes at least one wire loop.

7. The chip assembly according to claim 6, wherein each wire loop extends from the first substrate and is connected to contact pads on the second substrate.

8. The chip assembly according to claim 6, wherein a first wire loop extends from the first substrate and a second wire loop extends from the second substrate, and the first and second wire loops contact one another.

9. The chip assembly according to claim 1, wherein the at least one connection includes at least one plated via.

10. The chip assembly according to claim 9, wherein each plated via is created subsequent to assembly of the chip assembly.

11. The chip assembly according to claim 1, further comprising a spacer disposed between the first and second substrates.

12. The chip assembly according to claim 11, wherein the spacer includes an encapsulant passage.

13. The chip assembly according to claim 11, wherein the spacer includes at least one via.

14. The chip assembly according to claim 11, further comprising a plurality of spacers between the first and second substrates.

15. The chip assembly according to claim 14, wherein each spacer includes at least one via.

16. A chip assembly comprising:
a first unit including a first substrate and one or more first electronic components mounted to the first substrate;
a second unit including a second substrate and one or more second electronic components mounted to the second substrate;
a third unit including a third substrate and one or more third electronic components mounted to the third substrate; and
a connection between the first, second and third substrates,
wherein said first, second and third units are connected together so that the first electronic components project from the first substrate toward the second substrate and at least some of the second electronic components project from the second substrate toward the first substrate, and so that the third electronic components project from the third substrate toward the second substrate and at least some of the second electronic components project from the second substrate toward the third substrate, and at least some of the first electronic components extending between at least some of said second electronic components and at least some of the third electronic components extending between at least some of the second electronic components.

17. The chip assembly according to claim 16, wherein the connection between the first, second and third substrates includes a plurality of solder balls connecting said first, second and third units.

18. The chip assembly according to claim 16, wherein the connection between the first, second and third substrates includes a plurality of pins connecting said first, second and third units.

19. The chip assembly according to claim 16, wherein the connection between the first, second and third substrates includes a plurality of spring loaded contacts.

20. The chip assembly according to claim 16, wherein the connection between the first, second and third substrates includes a plurality of screws and rivets.

21. The chip assembly according to claim 16, wherein the connection between the first, second and third substrates includes a plurality of wire loops.

22. The chip assembly according to claim 21, wherein wire loops extend from the first substrate are connected to contact pads on the second substrate.

23. The chip assembly according to claim 21, wherein a first wire loop extends from the first substrate and a second wire loop extends from the second substrate, and the first and second wire loops contact one another.

24. The chip assembly according to claim 16, wherein the connection between the first, second and third substrates includes plated vias.

25. The chip assembly according to claim 24, wherein the plated vias are created subsequent to assembly of the chip assembly.

26. The chip assembly according to claim 16, wherein a distance between the first and second substrates is less than the total height of one said first electronic component and one said second electronic component.

27. The chip assembly according to claim 16, further comprising an encapsulant disposed between said first and second units and said second and third units.

28. The chip assembly according to claim 16, further comprising a spacer disposed between the first and second substrates and the second and third substrates.

29. The chip assembly according to claim 28, wherein the spacer includes an encapsulant passage.

30. The chip assembly according to claim 29, wherein the spacer includes at least one via.

31. The chip assembly according to claim 16, further comprising a plurality of spacers between the first and second substrates and the second and third substrates.

32. The chip assembly according to claim 31, wherein each spacer includes at least one via.

33. A chip system comprising:
a shell; and
a plurality of chip assemblies disposed within the shell,
wherein each of the assemblies includes a threaded exterior portion cooperating with a threaded interior portion of the shell.

34. The chip system of claim 33, wherein each of the assemblies is circular shaped and includes at least one axially and circumferentially extending contact.

35. The chip system of claim 34, wherein each contact extends substantially further in a circumferential direction than in an axial direction.

36. The chip system of claim 33, wherein the shell further includes at least one lid.
